(19) United States
(12) Patent Application Publication
(10) Pub. No.: US 2025/0358932 A1
(43) Pub. Date: Nov. 20, 2025

(54) Transparent Flexible Circuits

(71) Applicant: Xiamen Compass Technology Co., Ltd., Xiamen City (CN)

(72) Inventors: Kelvin Po Leung Pun, Hong Kong SAR (CN); Chee-Wah Cheung, Hong Kong SAR (CN); Jason Rotanson, Hong Kong SAR (CN); Xing Tianle, Hong Kong (CN)

(21) Appl. No.: 18/667,154

(22) Filed: May 17, 2024

(51) Int. Cl. H05K 1/03; G02B 6/42; H05K 1/02; H05K 3/38

(52) U.S. Cl. CPC H05K 1/0393; G02B 6/4259; H05K 1/0281; H05K 3/386; H05K 2201/0154; H05K 2201/0355

(57) ABSTRACT

A transparent flexible substrate structure comprises an optically transparent cyclo-olefin polymer flexible substrate, an optically transparent dielectric bonding film on the cyclo-olefin polymer surface, a monolayer graphene circuitry on the bonding film, copper traces on the bonding film and electrically connected to the graphene circuitry at edges of a transparent area, and a layer of transparent permanent resist on top of the graphene circuitry and portions of the copper traces.

### TECHNICAL FIELD

This application relates to producing a transparent flexible integrated circuit package, and more particularly, to producing a cyclo-olefin polymer flexible substrate with graphene circuitry for integrated circuit packaging and biocompatible sensors.

### BACKGROUND

Transparent conductive film (TCF) is a kind of film which can conduct electricity and has high transparency in the visible light range. The demand for TCF appears in various fields of the electronics industry, including organic light-emitting diodes (OLEDs), solar cells, and touch screens, for example. Since the discovery of Indium Tin Oxide (ITO), the contradiction between light transmission and electrical conductivity of substances has been solved. ITO as a TCF material has drawn attention for its low electrical sensitivity; however, from the standpoint of manufacturing, it has a high cost because of the scarcity of Indium (In) resources. Other materials used for TCF include carbon nanotubes, metal oxides, and graphene-silver nanowires.

Graphene as a single sheet transparent conducting material is a promising material for TCF. Graphene offers various potential advantages over ITO film including density, robustness, flexibility, chemical stability and cost. A sandwich structure of a AgNW layer between two graphene layers has shown better performance than commercial ITO films. Genetic and biochemical sensors composed of graphene have been developed.

Transparent sensors using graphene are taught in several U.S. Patents and Patent Applications including 10,871,466 (Mackin et al), 2012/0305892 (Thornton et al), 2022/0115230 (Lu et al), 2022/0003676 (Mazed), 2016/0330877 (Das), and 2016/0215217 (Akiyama et al).

### SUMMARY

A principal object of the present disclosure is to provide a transparent flexible substrate structure.

Another object of the disclosure is to provide a transparent flexible substrate with ultra-high circuit density graphene circuits.

A further object of the disclosure is to provide a multilayer transparent flexible substrate structure using cyclo-olefin polymer and graphene.

Yet another object is to provide a method for fabricating a transparent flexible substrate with ultra-high circuit density graphene circuits for communication devices.

Yet another object is to provide a method for fabricating a transparent flexible substrate with ultra-high circuit density graphene circuits for biocompatible sensors.

A still further object is to provide a method for fabricating a multilayer transparent flexible substrate structure using cyclo-olefin polymer and graphene.

In accordance with the objects of the present disclosure, a transparent flexible substrate structure is achieved comprising an optically transparent cyclo-olefin polymer flexible substrate, an optically transparent dielectric bonding film on the cyclo-olefin polymer surface, a monolayer graphene circuitry on the bonding film, copper traces on the bonding film and electrically connected to the graphene circuitry at edges of a transparent area, and a layer of transparent permanent resist on top of the graphene circuitry and portions of the copper traces.

Also in accordance with the objects of the present disclosure, a transparent flexible substrate structure is achieved comprising an optically transparent cyclo-olefin polymer flexible substrate, a first optically transparent dielectric bonding film on one surface of the cyclo-olefin polymer flexible substrate and a second optically transparent dielectric bonding film on an opposite surface of the cyclo-olefin polymer flexible substrate, a first monolayer graphene circuitry on the first bonding film and a second monolayer graphene circuitry on the second bonding film, first copper traces on the first bonding film and electrically connected to the first graphene circuitry at edges of a transparent area and second copper traces on the second bonding film and electrically connected to the second graphene circuitry at edges of the transparent area, wherein the first copper traces are connected to the second copper traces through copper filling via openings through all layers between the first and second copper traces, and a first layer of transparent permanent resist on top of the first graphene circuitry and portions of the first copper traces and a second layer of transparent permanent resist on top of the second graphene circuitry and portions of the second copper traces.

Also in accordance with the objects of the present disclosure, a method for fabricating a transparent flexible substrate is achieved. An optically transparent cyclo-olefin polymer flexible substrate is provided. A first optically transparent dielectric bonding film is laminated onto the cyclo-olefin polymer flexible substrate. A copper foil is provided having a monolayer graphene layer on one side of it. A first copper foil with monolayer graphene is laminated onto the first bonding film, the graphene side facing the first bonding film. The substrate is cured. Thereafter, the first copper foil is etched away leaving first copper traces in peripheral areas. Thereafter, a first layer of transparent permanent resist is applied on top of the first graphene layer and portions of the first copper traces and the transparent permanent resist is patterned. Thereafter, the graphene layer is etched using the patterned transparent permanent resist as an etching mask to form first graphene circuitry on the first bonding film.

### BRIEF DESCRIPTION OF THE DRAWINGS

In the accompanying drawings forming a material part of this description, there is shown:

FIGS. 1-5 schematically illustrate in cross-sectional representation steps in a first preferred embodiment of the present disclosure.

FIGS. 6-12 schematically illustrate in cross-sectional representation steps in a second preferred embodiment of the present disclosure.

### DESCRIPTION OF THE PREFERRED EMBODIMENTS

The present disclosure describes the construction and fabrication method for a transparent flexible substrate. A cyclo-olefin polymer (COP) base film material is used for the flexible transparent circuit of the present disclosure. COP is flexible and possesses a low dielectric constant/loss tangent and excellent biocompatibility and, thus, is suitable for both integrated circuit (IC) packaging of communication devices (mmWave) and biocompatible sensor devices.

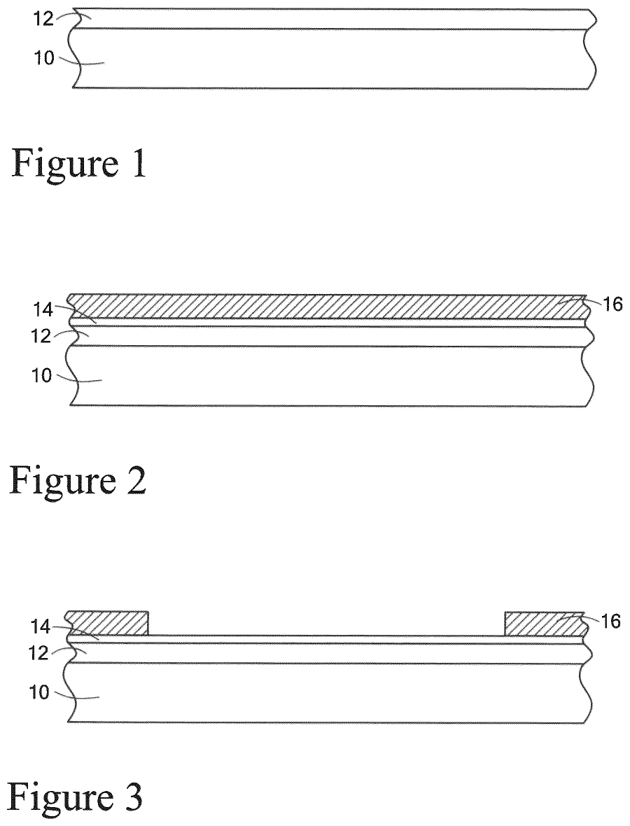

In the first preferred embodiment of the present disclosure, a fully transparent single metal layer flexible substrate structure is fabricated, as shown in FIGS. 1-5. Referring now more particularly to FIG. 1, there is shown a flexible dielectric substrate 10 comprising optically transparent cyclo-olefin polymer (COP) with a thickness range of 12.5 to 100 μm and a dielectric constant of <2.3. COP is the best choice for the flexible dielectric substrate because of its optical transparency, light weight, low exceptional dimension stability, high heat resistance, and high-frequency characteristics.

A layer 12 of optically transparent dielectric bonding film is laminated onto the COP substrate with thickness ranging from 15 to 50 μm and a dielectric constant of 2-2.6. The bonding film 12 may be an adhesive film reinforced with fibers, such as epoxy, cyanide ester, acrylic adhesive, modified polyimide (MPI) with epoxy, and the like.

Next, as shown in FIG. 2, copper foil 16 with a monolayer CVD (chemical vapor deposition) graphene 14 is laminated onto the bonding film with the side containing the CVD graphene facing the bonding film. The copper foil process provides better film uniformity and thickness control at higher thickness and lower manufacturing cost compared to PECVD or other processes.

Next, the film is cured with temperature and pressure, preferably at a temperature of between 12° and 200° C. and a pressure of 2 to 6 MPa for about 45 to 90 minutes. After curing, the copper foil will be etched away completely in the areas where transparency is desired and only the graphene will remain on the bonding film in those areas. Copper will remain in the areas where circuitry is desired.

FIG. 3 illustrates the substrate after copper foil etching. The remaining copper circuitry 16 is electrically connected to graphene 14 via the monolayer graphene sidewall to act as a contact pad for graphene circuit continuity testing. This is to achieve electrical connection in the z-direction between the graphene layer 14 and other layers as graphene is a monolayer conductor that only conducts electricity across the x-y plane but not in the z direction; thus, the electrical connection between graphene and copper can only be achieved in the x-y plane through the sidewall of both copper and graphene.

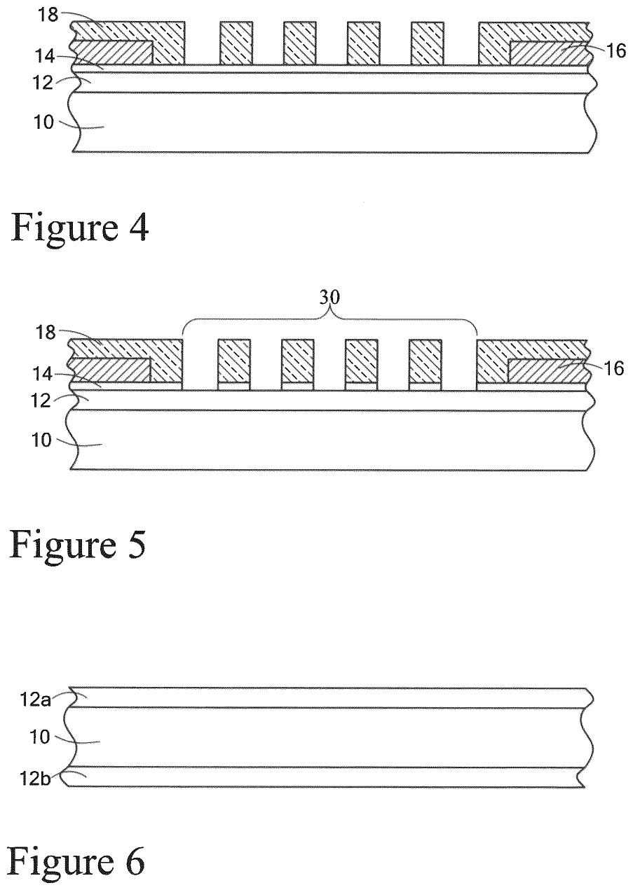

Now, a layer of transparent, photo-imageable permanent resist 18 is coated on top of both graphene and copper circuitry that acts as an electrical and mechanical insulation layer. It is a permanent resist that is able to form ultra-fine line circuitry and also act as a dielectric layer to protect the graphene circuitry. Then, the resist 18 is patterned for the graphene circuitry formation, as shown in FIG. 4.

Next, as shown in FIG. 5, the graphene layer 14 is etched using the resist 18 pattern to form the graphene circuitry. The circuitry 14 has fine line/space circuit formation down to 2/2 μm; that is, a trace width of 2 μm with 2 μm spacing. Circuitry line and space are affected by the thickness of the circuit itself. As etching is part of the circuitry formation, higher thickness will require more etching and thus enlarge the line and space geometry. Utilizing graphene that virtually has no thickness (only in the scale of a few nano-meters), only very minimal etching is required; thus, ultra-fine line/space circuitry can be formed. The graphene circuitry is covered by the permanent resist to provide mechanical protection and act as a dielectric to provide electrical insulation. The bonding film 12 itself is already a dielectric.

The transparent area 30 between the copper circuits 16 is shown. Components or devices can be connected to the copper traces if the application requires to enable product applications that requires transparency such as micro fluidic observation and display modules, for example.

In the second preferred embodiment of the present disclosure, a fully transparent double metal layer flexible substrate structure is fabricated, as shown in FIGS. 6-12. Referring now more particularly to FIG. 6, there is shown a flexible dielectric substrate 10 comprising optically transparent cyclo-olefin polymer (COP) with a thickness range of 12.5 to 100 μm and a dielectric constant of <2.3.

A layer of optically transparent dielectric bonding film 12a is formed on the top side of the flexible substrate 10 and a second layer of optically transparent dielectric bonding film 12b is formed on the bottom side of the flexible substrate 10. The bonding films 12a and 12b have a thickness ranging from 15 to 50 μm and a dielectric constant of 2-2.6.

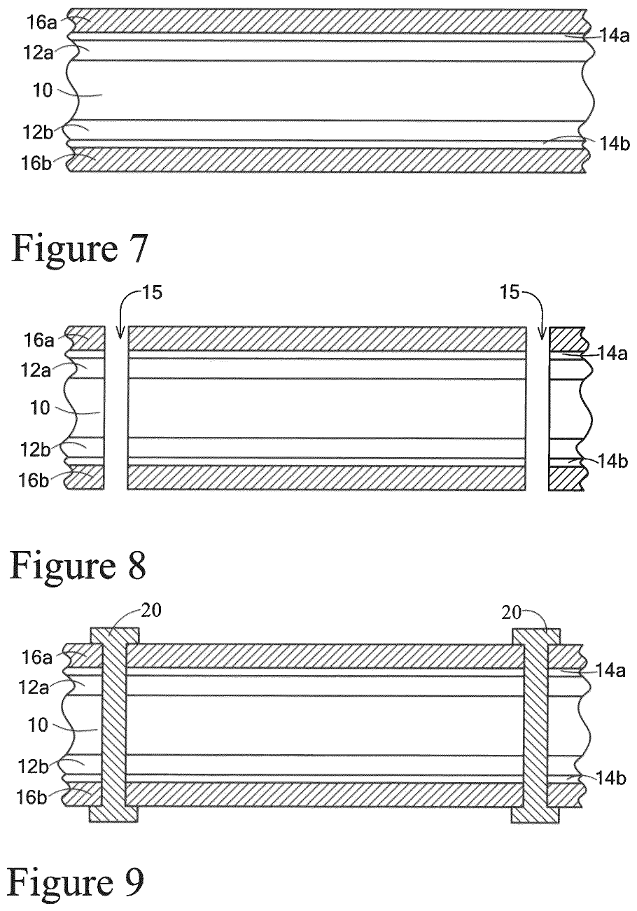

As shown in FIG. 7, copper foil with a monolayer CVD graphene is laminated onto each of the dielectric bonding films 12a and 12b, with the side containing the CVD graphene facing the bonding films. Copper foil 16a with graphene 14a is shown laminated onto bonding film 12a and copper foil 16b with graphene 14b is shown laminated onto bonding film 12b. Curing is performed as described above in the first embodiment.

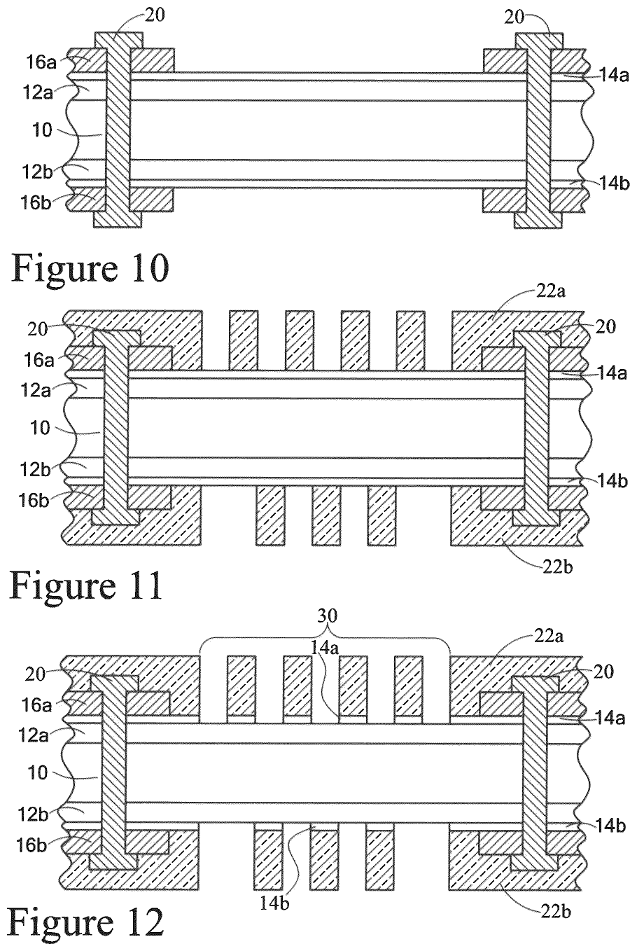

Now, vias 15 are opened through all of the layers, as shown in FIG. 8, in a peripheral area. The via openings 15 are filled with copper 20 in a button plating process to connect the two sides of the substrate, as illustrated in FIG. 9. Next, as shown in FIG. 10, the copper foil 16a and 16b will be etched away completely in the areas where transparency is desired and only the graphene 14a and 14b will remain on the bonding films 12a and 12b, respectively, in those areas. Copper will remain in the areas where circuitry is desired and in the filled vias 20.

Next, layers of transparent, photo-imageable permanent resist are coated on top of both graphene and copper circuitry on the top and bottom of the substrate, respectively, as shown in FIG. 11. The resist is patterned 22a for graphene circuitry formation on top of the graphene 14a and patterned 22b for graphene circuitry formation on top of the graphene 14b.

Graphene circuitry 14a and 14b are formed on top and bottom surfaces, respectively, by selective plasma etching, using the resist 22a and 22b, respectively, as masks, resulting in fine line/space circuit formation down to 2/2 μm.

The transparent area 30 between the filled copper vias 20 is shown. Components or devices can be connected to the copper traces if the application requires to enable product applications that requires transparency.

The flexible substrate device described in the two embodiments of the present disclosure has the following advantages:
1) Optically transparent material stack-up offers a significant advantage for viewing biology, display, touch screens, etc.
2) Graphene offers ultra-high circuitry density with excellent electrical, mechanical, and optical properties.
3) Multilayer flexible substrate offers high circuitry density and flexibility for sensor module miniaturization.

Although the preferred embodiment of the present disclosure has been illustrated, and that form has been described in detail, it will be readily understood by those skilled in the art that various modifications may be made therein without departing from the spirit of the disclosure or from the scope of the appended claims.

What is claimed is:

1. A transparent flexible substrate comprising:
an optically transparent cyclo-olefin polymer flexible substrate;
an optically transparent dielectric bonding film on said cyclo-olefin polymer surface;
a monolayer graphene circuitry on said bonding film;
copper traces on said bonding film and electrically connected to said graphene circuitry at edges of a transparent area; and
a layer of transparent permanent resist on top of said graphene circuitry and portions of said copper traces.

2. The device according to claim 1 wherein said cyclo-olefin polymer flexible substrate has a thickness of 12.5 to 100 μm and a dielectric constant of <2.3.

3. The device according to claim 1 wherein said dielectric bonding film comprises adhesive film reinforced with fibers, chosen from the group containing: epoxy, cyanide ester, acrylic adhesive, and modified polyimide (MPI) with epoxy and wherein said bonding film has a thickness of 15 tp 50 μm and a dielectric constant of 2 to 2.6.

4. The device according to claim 1 wherein said monolayer graphene circuitry has a thickness range of 2 to 10 nm and fine line/space circuit formation down to 2/2 μm.

5. A method for fabricating a transparent flexible substrate comprising:
providing an optically transparent cyclo-olefin polymer flexible substrate;
laminating a first optically transparent dielectric bonding film onto said cyclo-olefin polymer flexible substrate;
providing a copper foil having a monolayer graphene layer on one side of it;
laminating a first copper foil with first monolayer graphene on said first bonding film, said first graphene side facing said first bonding film;
thereafter curing said substrate;
thereafter etching away said first copper foil leaving first copper traces in peripheral areas;
thereafter applying a first layer of transparent permanent resist on top of said first graphene layer and portions of said first copper traces and patterning said transparent permanent resist; and
thereafter etching said first graphene layer using patterned said first transparent permanent resist as an etching mask to form first graphene circuitry on said first bonding film.

6. The method according to claim 5 wherein said cyclo-olefin polymer flexible substrate has a thickness of 12.5 to 100 μm and a dielectric constant of <2.3.

7. The method according to claim 5 wherein said first dielectric bonding film comprises adhesive film reinforced with fibers, chosen from the group containing: epoxy, cyanide ester, acrylic adhesive, and modified polyimide (MPI) with epoxy and wherein said bonding film has a thickness of 15 to 50 μm and a dielectric constant of 2 to 2.6.

8. The method according to claim 5 wherein said monolayer graphene layer has a thickness range of 2 to 10 nm.

9. The method according to claim 5 wherein said curing said substrate is performed at a temperature of between 12° and 200° C. and a pressure of 2 to 6 MPa for 45 to 90 minutes.

10. The method according to claim 5 wherein said first graphene circuitry has fine line/space circuit formation down to 2/2 μm.

11. The method according to claim 5 further comprising:
laminating a second optically transparent dielectric bonding film onto an opposite side of said cyclo-olefin polymer flexible substrate as said first optically transparent dielectric bonding film;
laminating a second copper foil with second monolayer graphene on said second bonding film, said second graphene side facing said second bonding film;
thereafter drilling at least one via hole all the way through all layers in a peripheral area;
thereafter selectively plating said at least one via hole with copper to fully fill said via hole;
thereafter etching away said second copper foil leaving second copper traces in said peripheral areas;
thereafter applying a second layer of transparent permanent resist on top of said second graphene layer and portions of said second copper traces and patterning said second transparent permanent resist; and
thereafter etching said second graphene layer using patterned said second transparent permanent resist as an etching mask to form second graphene circuitry on said second bonding film.

12. The method according to claim 11 wherein said second graphene circuitry has fine line/space circuit formation down to 2/2 μm.

13. A method for fabricating a transparent flexible substrate comprising:
providing an optically transparent cyclo-olefin polymer flexible substrate;
laminating a first optically transparent dielectric bonding film onto said cyclo-olefin polymer flexible substrate;
providing a copper foil having a monolayer graphene layer on one side of it;
laminating a first copper foil with monolayer graphene on said first bonding film, said graphene side facing said first bonding film;
laminating a second optically transparent dielectric bonding film onto an opposite surface of said cyclo-olefin polymer flexible substrate from said first dielectric bonding film;
laminating a second copper foil with monolayer graphene on said second bonding film, said graphene side facing said second bonding film;
thereafter curing said substrate;
thereafter drilling at least one via hole all the way through all layers in a peripheral area;
thereafter selectively plating said at least one via hole with copper to fully fill said via hole;
thereafter etching away said first and second copper foil leaving first and second copper traces in said peripheral area;
thereafter applying a first layer of transparent permanent resist on top of said first graphene layer and portions of said first copper traces;
thereafter applying a second layer of transparent permanent resist on top of said second graphene layer and portions of said second copper traces;
thereafter etching first and second said graphene layers using patterned said first and second transparent permanent resist as etching masks to form first graphene circuitry on said first bonding film and second graphene circuitry on said second bonding film wherein electrical connection is made between said first copper traces on said first bonding film and said first graphene circuitry at edges of a transparent area and between said second copper traces on said second bonding film and said second graphene circuitry at edges of said transparent area, wherein said first copper traces are connected to said second copper traces through said copper filling said at least one via hole through all layers between said first and second copper traces.

14. The method according to claim 13 wherein said first and second dielectric bonding films comprise adhesive film reinforced with fibers, chosen from the group containing: epoxy, cyanide ester, acrylic adhesive, and modified polyimide (MPI) with epoxy and wherein said bonding film has a thickness of 15 to 50 μm and a dielectric constant of 2 to 2.6.

15. The method according to claim 13 wherein said first and second graphene circuitry have fine line/space circuit formation down to 2/2 μm.

16. A transparent flexible substrate comprising:
an optically transparent cyclo-olefin polymer flexible substrate;
a first optically transparent dielectric bonding film on one surface of said cyclo-olefin polymer flexible substrate and a second optically transparent dielectric bonding film on an opposite surface of said cyclo-olefin polymer flexible substrate;
a first monolayer graphene circuitry on said first bonding film and a second monolayer graphene circuitry on said second bonding film;
first copper traces on said first bonding film and electrically connected to said first graphene circuitry at edges of a transparent area and second copper traces on said second bonding film and electrically connected to said second graphene circuitry at edges of said transparent area, wherein said first copper traces are connected to said second copper traces through copper filling via openings through all layers between said first and second copper traces; and
a first layer of transparent permanent resist on top of said first graphene circuitry and portions of said first copper traces and a second layer of transparent permanent resist on top of said second graphene circuitry and portions of said second copper traces.

17. The device according to claim 16 wherein said cyclo-olefin polymer flexible substrate has a thickness of 12.5 to 100 μm and a dielectric constant of <2.3.

18. The device according to claim 16 wherein said dielectric bonding film comprises adhesive film reinforced with fibers, chosen from the group containing: epoxy, cyanide ester, acrylic adhesive, and modified polyimide (MPI) with epoxy and wherein said bonding film has a thickness of 15 tp 50 μm and a dielectric constant of 2 to 2.6.

19. The device according to claim 16 wherein said monolayer graphene circuitry has a thickness range of 2 to 10 nm and fine line/space circuit formation down to 2/2 μm.
